(19) United States
(12) Patent Application Publication
(10) Pub. No.: US 2026/0033135 A1
(43) Pub. Date: Jan. 29, 2026

(54) ANTI-BLUE-RAY DEVICE, LIGHT-EMITTING DEVICE AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN); BEIJING BOE TECHNOLOGY DEVELOPMENT CO., LTD., Beijing (CN)

(72) Inventor: Shun Wang, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/992,401

(22) PCT Filed: May 17, 2024
(86) PCT No.: PCT/CN2024/094044

§ 371 Date: Jan. 8, 2025

(30) Foreign Application Priority Data
Jun. 30, 2023 (CN) 202310798331.3

(51) Int. Cl. H10K 50/858; H10K 59/50; H10K 102/00

(52) U.S. Cl. CPC H10K 50/858; H10K 59/50; H10K 2102/351

(57) ABSTRACT

An anti-blue light device, a light-emitting device and a display apparatus are provided by the present disclosure, which relates to the technical field of displaying. The anti-blue light device includes: at least one refractive index adjustment layer arranged in layer configuration, wherein the refractive index adjustment layer includes a first film layer and a second film layer arranged in layer configuration; the first film layer is disposed adjacent to a light incident surface of the anti-blue light device, and a refractive index of the second film layer is adjustable under an action of a driving signal; in a first mode, an absolute value of a difference between a refractive index of the first film layer and the refractive index of the second film layer is less than or equal to a first threshold; and in a second mode, the difference between the refractive index of the second film layer and the refractive index of the first film layer is greater than or equal to a second threshold, and the second threshold is greater than the first threshold.

### CROSS-REFERENCE TO RELATED APPLICATION

This application claims the priority of the Chinese Patent application filed on Jun. 30, 2023 before the China National Intellectual Property Administration with the application number of 202310798331.3, and the title of “ANTI-BLUE-RAY DEVICE, LIGHT-EMITTING DEVICE AND DISPLAY APPARATUS”, which is incorporated herein in its entirety by reference.

### FIELD

Embodiments of the present application relate to the technical field of displaying and, more particularly, to an anti-blue light device, a light-emitting device and a display apparatus.

### BACKGROUND

An organic light-emitting diode (OLED) has the advantages of all-solid state, autonomous light-emitting, high brightness, high resolution, wide viewing angle, fast response speed, thin thickness, small size, light weight, usable flexible substrate, low-voltage direct current drive, low power consumption, wide operating temperature range, etc., which makes its application market very wide.

### SUMMARY

The following technical solutions are adopted by the present disclosure.

An anti-blue light device is provided by a first aspect of an embodiment of the present application, which includes:
at least one refractive index adjustment layer arranged in layer configuration, wherein each of the at least one refractive index adjustment layer includes a first film layer and a second film layer arranged in layer configuration; the first film layer is disposed adjacent to a light incident surface of the anti-blue light device, and a refractive index of the second film layer is adjustable under an action of a driving signal;
wherein in a first mode, an absolute value of a difference between a refractive index of the first film layer and the refractive index of the second film layer is less than or equal to a first threshold; and in a second mode, the difference between the refractive index of the second film layer and the refractive index of the first film layer is greater than or equal to a second threshold, and the second threshold is greater than the first threshold.

In an optional embodiment, the first threshold is greater than or equal to 0 and less than or equal to 0.02; and the second threshold is greater than or equal to 0.04 and less than or equal to 0.06.

In an optional embodiment, the refractive index of the first film layer is greater than or equal to a third threshold and less than or equal to a fourth threshold; and

the refractive index of the second film layer is greater than or equal to the third threshold and less than or equal to a fifth threshold.

In an optional embodiment, the third threshold is greater than or equal to 1.45 and less than or equal to 1.55; the fourth threshold is greater than or equal to 1.65 and less than or equal to 1.75; and the fifth threshold is greater than or equal to 1.75 and less than or equal to 1.85.

In an optional embodiment, a quantity of the at least one refractive index adjustment layer is greater than or equal to 3, and a sum of thicknesses of the at least one refractive index adjustment layer arranged in layer configuration is less than or equal to 20 μm.

In an optional embodiment, the driving signal is an electrical signal, and the second film layer includes a driving electrode and a liquid crystal layer; the driving electrode is configured to form an electric field under an action of the electrical signal to drive deflection of liquid crystal molecules in the liquid crystal layer to adjust the refractive index of the second film layer.

In an optional embodiment, the driving signal is an acoustic signal, and the second film layer includes an acousto-optic crystal; and the acousto-optic crystal is configured to change a refractive index of the acousto-optic crystal under an action of the acoustic signal.

In an optional embodiment, the driving signal is an optical signal, and the second film layer includes a photonic crystal; and the photonic crystal is configured to change a refractive index of the photonic crystal under an action of the optical signal.

In an optional embodiment, a material of the first film layer includes at least one of silicon nitride, silicon oxide and silicon oxynitride.

In an optional embodiment, a thickness of the first film layer is the same as a thickness of the second film layer; a quantity of the at least one refractive index adjustment layer is an even number greater than 3, and a thickness of each of the at least one refractive index adjustment layer is greater than or equal to 130 nm and less than or equal to 140 nm.

A light-emitting device is provided by a second aspect of an embodiment of the present application, which includes:
at least one light-emitting unit; and
the anti-blue light device according to any one of embodiments as stated in the first aspect, wherein the anti-blue light device is located at a light-emitting side of the at least one light-emitting unit.

In an optional embodiment, the light-emitting device includes a plurality of light-emitting units, and the plurality of light-emitting units are arranged in layer configuration in a light-emitting direction of the plurality of light-emitting units; and
a target parameter value of at least one of the plurality of the light-emitting units is greater than or equal to a first critical value and less than or equal to a second critical value; a sum of target parameter values of all light-emitting units is greater than or equal to a first total critical value and less than or equal to a second total critical value; the first total critical value is a product of the first critical value and a quantity of the plurality of light-emitting units, and the second total critical value is a product of the second critical value and the quantity of the plurality of light-emitting units; and the target parameter value is at least one of a wavelength corresponding to an intrinsic spectral peak, an intrinsic spectral full width at half maximum and an intensity of an intrinsic spectral target wavelength.

In an optional embodiment, when the target parameter value is the wavelength corresponding to the intrinsic spectral peak, the first critical value is a first wavelength, and the first wavelength is greater than or equal to 455 nm and less than or equal to 465 nm; and the second critical value is a second wavelength, and the second wavelength is greater than or equal to 465 nm and less than or equal to 475 nm.

In an optional embodiment, when the target parameter value is the intrinsic spectral full width at half maximum, the first critical value is a first full width at half maximum, and the first full width at half maximum is greater than or equal to 5 nm and less than or equal to 15 nm; and the second critical value is a second full width at half maximum, and the second full width at half maximum is greater than or equal to 25 nm and less than or equal to 35 nm.

In an optional embodiment, the intrinsic spectral target wavelength is 450 nm; when the target parameter value is an intensity of the intrinsic spectral target wavelength, the first critical value is a first intensity, and the first intensity is greater than or equal to 0 and less than or equal to 0.1; and the second critical value is a second intensity, and the second intensity is greater than or equal to 0.25 and less than or equal to 0.4.

In an optional embodiment, the light-emitting device further includes:
a first electrode and a second electrode, wherein the at least one light-emitting unit is located between the first electrode and the second electrode, and the anti-blue light device is disposed at a side of the second electrode facing away from the first electrode.

In an optional embodiment, a thickness of the second electrode is greater than or equal to 12 nm.

In an optional embodiment, the light-emitting device further includes:
an optical coupling layer disposed between the second electrode and the anti-blue light device.

In an optional embodiment, a product of a refractive index of the optical coupling layer and a thickness of the optical coupling layer is greater than or equal to 150.

A display apparatus is provided by a third aspect of the embodiments of the present application, which includes a base substrate and the plurality of light-emitting devices according to any one of embodiments as stated in the second aspect disposed on the base substrate.

The above description is only a summary of technical schemes of the present disclosure, which can be implemented according to contents of the specification in order to better understand technical means of the present disclosure; and in order to make above and other objects, features and advantages of the present disclosure more obvious and understandable, detailed description of the present disclosure is particularly provided in the following.

### BRIEF DESCRIPTION OF THE DRAWINGS

In order to more clearly illustrate the technical solutions of the embodiments of the present disclosure or the related art, the drawings that are required to describe the embodiments or the related art may be briefly introduced below. Apparently, the drawings that are described below are some embodiments of the present disclosure, and a person skilled in the art can obtain other drawings according to these figures without paying creative work.

FIG. 1 exemplarily shows a schematic structural diagram of an anti-blue light device according to the present disclosure;

FIG. 2 exemplarily shows a schematic blue light spectrum diagram in a first mode according to the present disclosure;

FIG. 3 exemplarily shows a schematic blue light spectrum diagram in a second mode according to the present disclosure;

FIG. 4 exemplarily shows a schematic reflectance spectrum diagram of a refractive index adjustment layer in a second mode according to the present disclosure;

FIG. 5 exemplarily shows a schematic structural diagram of a light-emitting device according to the present disclosure; and

FIG. 6 exemplarily shows a schematic structural diagram of a light-emitting unit according to the present disclosure.

Description of reference numerals: 100—first electrode, 200—second electrode, 300—light-emitting unit, 301—first carrier layer, 3011—hole injection layer, 3012—hole transport layer, 3013—electron block layer, 302—second carrier layer, 3021—hole block layer, 3022—electron transport layer, 3023—electron injection layer, 303—light-emitting layer, 400—connection layer, 500—anti-blue light device, 501—refractive index adjustment layer, 501-1—first film layer, 501-2—second film layer, 600—optical coupling layer, and 700—encapsulation layer.

### DETAILED DESCRIPTION

In order to make purposes, technical schemes and advantages of embodiments of this disclosure more clearer, the technical solutions in the embodiments of this disclosure will be described clearly and completely with reference to the drawings in the embodiments of this disclosure; and it is obvious that the described embodiments are a part of the embodiments of this disclosure, but not all of embodiments. On a basis of the embodiments in the present disclosure, all other embodiments obtained by a person skilled in the art without paying creative effort belongs to a protection scope of this disclosure.

Display screens are constantly developing towards high pixels, large color gamut and low power consumption. Compared with TFT-LCD, an OLED (organic light-emitting diode) flexible display screen has obvious advantages, such as foldability and bendability, making the flexible screen become a trend in the development of display screens and highly favored by electronic device enthusiasts. Therefore, the requirements for the device efficiency and service life of OLED devices in the art are increasingly high. Although many high-efficiency and long-service life OLED devices have been currently developed to meet usage requirements, they still cannot fully satisfy the current industry's pursuit of display effect in practical application process. In addition to the pursuit of color saturation and brightness, whether the light emitted by the OLED devices may cause harm to the human eye has also become a problem to be considered today.

Long-term exposure to blue light may lead to vision decreasing or even loss, with short-wave blue light with a wavelength between 400 nm and 460 nm being the most harmful to the human eye. In the field of displaying, blue light mainly comes from LCD display apparatuses with LEDs being the backlight sources. The OLED has the characteristic of self-emission, and the wavelength of the produced blue light is mainly concentrated at 460 nm. Although the harmful blue light produced by the OLED with a wavelength between 420 nm and 460 nm is lower than the harmful blue light produced by the LCD, the harmful blue light with a wavelength between 420 nm and 460 nm still exists. Therefore, it is necessary to reduce the intensity of the harmful blue light of the OLED and improve the eye protection effect of the OLED apparatus.

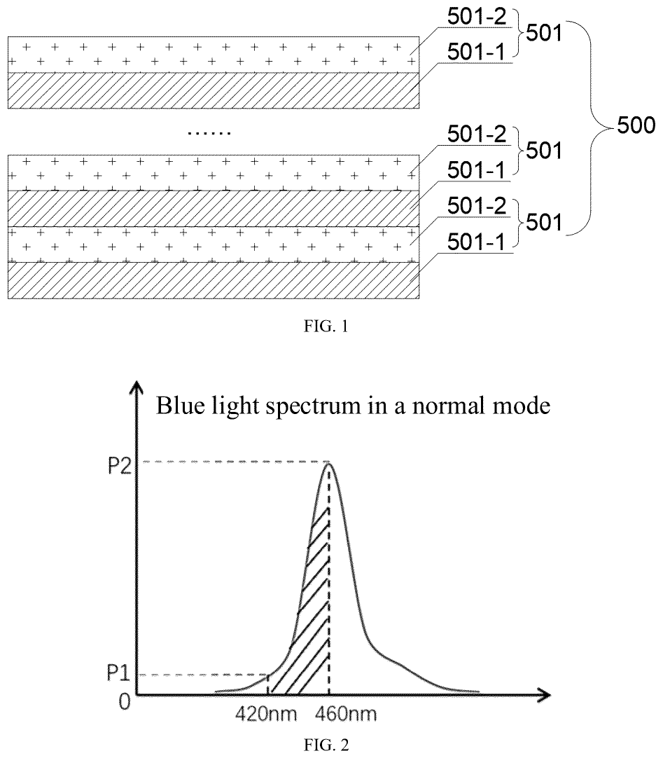

In view of this, an anti-blue light device is provided by an embodiment of the present disclosure. FIG. 1 exemplarily shows a schematic structural diagram of an anti-blue light device according to the present disclosure. As shown in FIG. 1, the anti-blue light device 500 includes at least one refractive index adjustment layer 501 arranged in layer configuration. Each of the at least one refractive index adjustment layer 501 includes a first film layer 501-1 and a second film layer 501-2 arranged in layer configuration, and the first film layer 501-1 is disposed adjacent to a light incident surface of the anti-blue light device 500.

In an embodiment of the present disclosure, a refractive index of the second film layer 501-2 is adjustable under the action of driving signal. Specifically, the driving signal includes a driving signal in a first mode and a driving signal in a second mode. The refractive index of the second film layer 501-2 is adjusted through the driving signal in the first mode, so that the refractive index of the first film layer 501-1 is close to the refractive index of the second film layer 501-2. Thus, harmful blue light (blue light with a wavelength between 420 nm and 460 nm) is directly transmitted through the anti-blue light device 500 without reflection, and it is realized that normal light is emitted. The refractive index of the second film layer 501-2 is adjusted through the driving signal in the second mode, so that the second film layer 501-2 with an adjusted refractive index plays a role in limiting on the harmful blue light, and a proportion of the intensity of the blue light with a wavelength between 420 nm and 460 nm in the emitted light to the total blue light spectral intensity is reduced, thereby an eye protection effect is achieved.

In an embodiment of the present disclosure, the first mode is a mode that may not limit the emitted light (for example, the first mode may be referred to as a common mode or a normal mode). At this moment, the proportion of the intensity of the blue light with a wavelength between 420 nm and 460 nm in the emitted light to the total blue light spectral intensity is relatively large. Exemplarily, in the first mode, the proportion of the intensity of the blue light with a wavelength between 420 nm and 460 nm in the emitted light to the total blue light spectral intensity is greater than 30%. Specifically, in the first mode, the refractive index of the first film layer 501-1 is close to the refractive index of the second film layer 501-2. At this moment, the refractive index adjustment layer 501 including the first film layer 501-1 and the second film layer 501-2 with similar refractive indexes may not have a limiting effect on the emitted light, and the light passes through the layered structures in the light-emitting device and the anti-blue light device 500 including at least one refractive index adjustment layer 501 arranged in layer configuration. Finally, the emitted light is incident into the air, and the intensity of the blue light in the range of 420 nm-460 nm in the blue light spectrum is large.

In an embodiment of the present disclosure, the second mode is a mode in which the emission of the harmful blue light in the emitted light is restricted under an action of adjustment of the driving signal to achieve an eye protection effect (for example, the second mode may be referred to as an eye protection mode or a blue light attenuation mode). Exemplarily, in the second mode, the proportion of the intensity of the blue light with a wavelength between 420 nm and 460 nm in the emitted light to the total blue light spectral intensity is less than or equal to 30%. The eye protection effect is a beneficial effect of reducing the visual fatigue of the user and reducing the damage of light with a specific wavelength (such as short-wave blue light between 420 nm and 460 nm) to the human eye (for example, switching the emitted light of the light-emitting device from a narrow viewing angle to a wide viewing angle to achieve the eye protection effect). Specifically, in the second mode, the refractive index of the second film layer 501-2 is changed under the action of the driving signal, so that the changed second film layer 501-2 has a larger refractive index than the first film layer 501-1. At this moment, the second film layer 501-2 in the refractive index adjustment layer 501 reflects harmful blue light (blue light with a wavelength between 420 nm and 460 nm) to a certain extent, so that the light passes through the layered structures in the light-emitting device and the anti-blue light device 500 including at least one refractive index adjustment layer 501 arranged in layer configuration. Finally, the emitted light is incident into the air, and the proportion of the intensity of the blue light in the range of 420 nm-460 nm in the blue light spectrum to the total blue light spectral intensity is reduced.

Specifically, in the first mode, an absolute value of a difference between the refractive index of the first film layer 501-1 and the refractive index of the second film layer 501-2 is less than or equal to a first threshold, so that in the first mode, the refractive index of the first film layer 501-1 is close to the refractive index of the second film layer 501-2. In the second mode, the difference between the refractive index of the second film layer 501-2 and the refractive index of the first film layer 501-1 is greater than or equal to a second threshold, and the second threshold is greater than the first threshold, so that in the second mode, the second film layer 501-2 has a larger refractive index than the first film layer 501-1.

In an optical embodiment, the first threshold is greater than or equal to 0 and less than or equal to 0.02. The second threshold is greater than or equal to 0.04 and less than or equal to 0.06. Exemplarily, the first threshold is 0.01, and the second threshold is 0.05. It should be noted that the above-described example is only one preferred case provided by the embodiments of the present disclosure, and numerical values of the first threshold and the second threshold involved in the embodiments of the present disclosure may be determined according to the actual situation, and which is not limited by the present disclosure herein.

In the first mode, the refractive index of the first film layer and the refractive index of the second film layer satisfy the following formula:

$$\vert {n}_{2} - {n}_{1} \vert \leq {A}_{1} ; \\ 0 \leq {A}_{1} \leq 0 \text{.02} ;$$

wherein n₁ is the refractive index of the first film layer in the first mode; n₂ is the refractive index of the second film layer in the first mode; and A₁ is the first threshold.

In the second mode, the refractive index of the first film layer is the same as the refractive index of the first film layer in the first mode, and the refractive index of the second film layer is adjusted by the driving signal to be different from the refractive index of the second film layer in the first mode. In the second mode, the refractive index of the first film layer and the refractive index of the second film layer satisfy the following formula:

$$\vert {n}_{2}^{′} - {n}_{1}^{′} \vert \geq {A}_{2} ; \\ 0.04 \leq {A}_{2} \leq 0.06 ; \\ {n}_{1}^{′} = {n}_{1} , {n}_{2}^{′} > {n}_{2} , {A}_{2} > {A}_{1} ;$$

wherein

$${n}_{1}^{′}$$

is the refractive index of the first film layer in the second mode;

$${n}_{2}^{′}$$

is the refractive index of the second film layer in the second mode; A₂ is the second threshold; n₁ is the refractive index of the first film layer in the first mode; and n₂ is the refractive index of the second film layer in the first mode; and A₁ is the first threshold.

In an embodiment of the present disclosure, FIG. 2 exemplarily shows a schematic blue light spectrum diagram in the first mode according to the present disclosure. As shown in FIG. 2, a shaded part represents the intensity of the blue light in the range of 420 nm-460 nm, and the curve represents the total blue light spectral intensity. In the first mode, the absolute value of the difference between the refractive index of the first film layer and the refractive index of the second film layer is less than or equal to the first threshold, so that the refractive index of the first film layer is very close to the refractive index of the second film layer, and the second film layer does not reflect the harmful blue light to a large extent in the first mode. The light passes through the layered structures in the light-emitting device and the anti-blue light device 500 including at least one refractive index adjustment layer 501 arranged in layer configuration. Finally, the emitted light is incident into the air, and the intensity of the blue light in the range of 420 nm-460 nm in the blue light spectrum is large, accounting for more than 30% and less than or equal to 40% of the total blue light spectral intensity (as shown in FIG. 2, a ratio of an area of the shaded part to a total area enclosed by the spectrum).

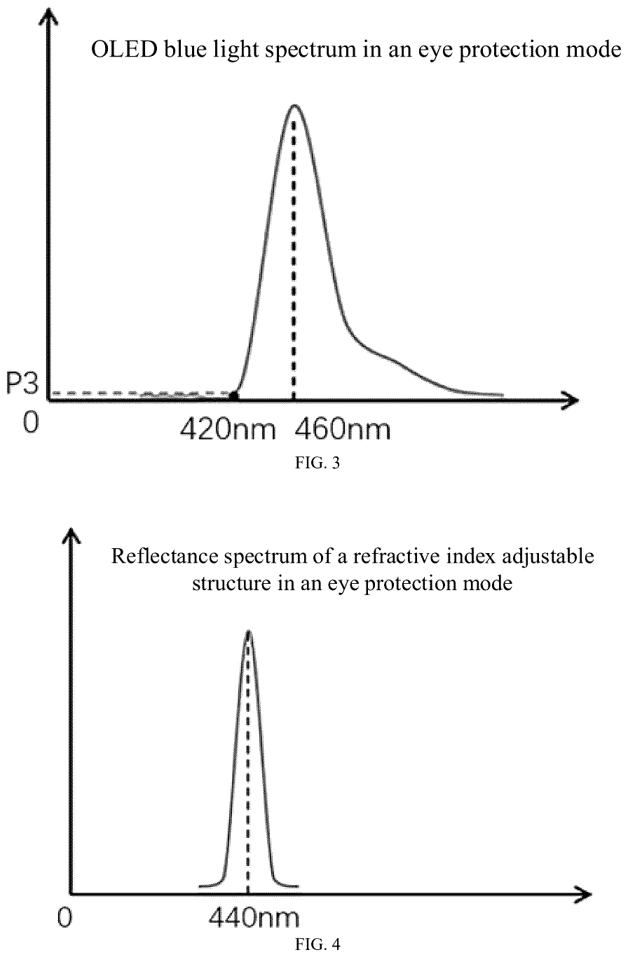

FIG. 3 exemplarily shows a schematic blue light spectrum diagram in the second mode according to the present disclosure. As shown in FIG. 3, in the second mode, the difference between the refractive index of the second film layer and the refractive index of the first film layer is greater than or equal to the second threshold, so that the refractive index of the second film layer is greater than the refractive index of the first film layer. The second film layer may reflect the harmful blue light to a greater extent in the second mode due to its greater refractive index. FIG. 4 exemplarily shows a schematic reflectance spectrum diagram of a refractive index adjustment layer in the second mode according to the present disclosure. As shown in FIG. 4, the refractive index adjustment layer (a refractive index adjustable structure shown in FIG. 4) has the largest reflection intensity for blue light in the range of 420 nm-460 nm (as shown in FIG. 4, a symmetrical wavelength range peaking at 440 nm). The light reaches the anti-blue light device including at least one refractive index adjustment layer arranged in layer configuration after passing through the layered structures in the light-emitting device, and the blue light in the range of 420 nm-460 nm in the blue light spectrum is filtered out from the emitted light through reflection of the second film layer in the second mode in the refractive index adjustment layer, so that the proportion of the intensity of the blue light in the range of 420 nm-460 nm in the blue light spectrum of the emitted light incident into the air is reduced, accounting for less than or equal to 30% of the total blue light spectral intensity (as shown in FIG. 3, a ratio of an area under the curve in the range of 420 nm-460 nm to a total area enclosed by the spectrum).

In an embodiment of the present disclosure, the refractive index of the second film layer in the refractive index adjustment layer is adjusted by the driving signal, so that the second film layer in the second mode may reflect blue light in the range of 420 nm-460 nm in the blue light spectrum. Thus, the proportion of harmful blue light originally accounting for more than 30% in the total blue light spectral intensity is reduced to less than 30%, and the intensity of harmful blue light in the emitted light received by the user is reduced, thereby playing a role in effectively protecting the eyes of the user.

In an optical embodiment, in order to enable the first film layer 501-1 and the second film layer 501-2 to effectively transmit light while ensuring that the refractive index of the second film layer may be adjusted between the first mode and the second mode based on the driving signal, in an embodiment of the present disclosure, the refractive index of the first film layer is greater than or equal to a third threshold and less than or equal to a fourth threshold. The refractive index of the second film layer is greater than or equal to the third threshold and less than or equal to a fifth threshold.

In an optical embodiment, the third threshold is greater than or equal to 1.45 and less than or equal to 1.55. The fourth threshold is greater than or equal to 1.65 and less than or equal to 1.75. The fifth threshold is greater than or equal to 1.75 and less than or equal to 1.85. Exemplarily, the third threshold is equal to 1.5, the fourth threshold is equal to 1.7, and the fifth threshold is equal to 1.8. It should be noted that the above-described example is only one preferred case provided by the embodiments of the present disclosure, and numerical values of the third threshold, the fourth threshold and the fifth threshold involved in the embodiments of the present disclosure may be determined according to the actual situation, which is not limited by the present disclosure herein.

In an embodiment of the present disclosure, the thickness of each refractive index adjustment layer in the anti-blue light device is determined according to the refractive index of the first film layer and the refractive index of the second film layer. The thickness of each refractive index adjustment layer may be equivalent to a distance between centers of the first film layers in two adjacent refractive index adjustment layers, or may be equivalent to a distance between centers of the second film layers in two adjacent refractive index adjustment layers. Specifically, reflected light whose wavelength satisfies the Bragg formula is reflected at the second film layer of the refractive index adjustment layer and cannot transmit the refractive index adjustment layer, so that the thickness of each refractive index adjustment layer satisfies the Bragg formula shown below:

$$2 {n}_{1} L sin θ = λ$$

wherein n₁ is the refractive index of the first film layer in the first mode; L is the thickness of the refractive index adjustment layer; and θ is an incident angle of incident light; λ is the wavelength of light.

In an optical embodiment, in order to ensure that the refractive index adjustment layer 501 may effectively reflect blue light of a specific wavelength under actions of different driving signals, at least one refractive index adjustment layer is arranged in layer configuration in the anti-blue light device 500. Moreover, the quantity of the at least one refractive index adjustment layer is greater than or equal to 3, and a sum of thicknesses of the at least one refractive index adjustment layer arranged in layer configuration is less than or equal to 20 μm. Exemplarily, if the thickness of the refractive index adjustment layer is determined to be 100 nm based on the Bragg formula and the refractive indexes of the first film layer and the second film layer, at least three refractive index adjustment layers with the thickness of 100 nm need to be disposed in the anti-blue light device, and not more than 200 refractive index adjustment layers are disposed (a sum of the thicknesses of 200 refractive index adjustment layers with a thickness of 100 nm is 20 μm). It should be noted that the above-mentioned example is only a specific implementation proposed to enable a person skilled in the art to better understand the solution of the present disclosure, and the actual quantity of the refractive index adjustment layers may be determined according to the actual situation, which is not limited by the present disclosure herein.

In an optical embodiment, in each refractive index adjustment layer 501, the thickness of the first film layer 501-1 is the same as the thickness of the second film layer 501-2. The quantity of the refractive index adjustment layers 501 is an even number greater than 3, for example, 4, 6, and 8. The thickness of the refractive index adjustment layer 501 is greater than or equal to 130 nm and less than or equal to 140 nm.

In an embodiment of the present application, a material of the first film layer includes at least one of silicon nitride, silicon oxide and silicon oxynitride. The material of the first film layer may not cause a change in refractive index due to the adjustment of the driving signals, so that the refractive index of the first film layer in the first mode and the refractive index of the first film layer in the second mode are the same. The second film layer includes a liquid crystal layer configured to refract and/or reflect light, and a material of the liquid crystal layer is a material that may response to the driving signal.

In an embodiment of the present application, the mode of the anti-blue light device is adjusted by the driving signals. Specifically, the refractive index of the second film layer in each refractive index adjustment layer is adjusted by the driving signals. In an optical embodiment, the driving signal is an electrical signal, and the second film layer includes a driving electrode configured to receive the electrical signal and a liquid crystal layer. A material of the liquid crystal layer is a nematic liquid crystal, such as an E7 nematic liquid crystal. Under the adjustment of different driving signals, liquid crystal molecules of the nematic liquid crystal are deflected to different degrees, thereby it is realized that the refractive index of the second film layer (liquid crystal layer) is adjusted based on the driving signals. Specifically, in the second mode, the driving electrode in the second film layer receives the electrical signal and forms an electric field under the action of the electrical signal, and the electric field drives the liquid crystal molecules in the liquid crystal layer to deflect, so that the refractive index of the second film layer is increased. On the premise of satisfying the Bragg formula, the blue light in the range of 420 nm-460 nm in the blue light spectrum is effectively reflected, so that the proportion of the intensity of the blue light in the range of 420 nm-460 nm in the blue light spectrum of the emitted light incident into the air is reduced.

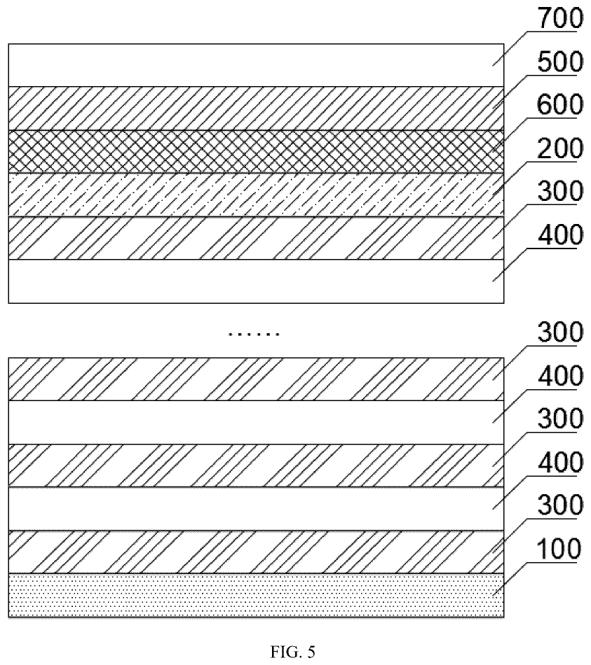

In an optical embodiment, FIG. 5 exemplarily shows a schematic structural diagram of a light-emitting device according to the present disclosure. As shown in FIGS. 1 and 5, a driving electrode may be disposed at two sides of the second film layer 501-2, so that the second film layer 501-2 changes its own refractive index under the action of a driving voltage difference between the two electrodes. Alternatively, a driving electrode may be disposed at two sides of the anti-blue light device 500, so that the anti-blue light device 500 changes its own refractive index under the action of a driving voltage difference between the two electrodes.

In an optical embodiment, as shown in FIGS. 1 and 5, a driving electrode may be disposed at a light-emitting side of the second film layer 501-2 (for example, disposed at a side of an encapsulation layer 700 facing away from a first electrode 100), and a second electrode 200 (for example, a cathode) is reused, so that the second film layer 501-2 changes its own refractive index under the action of a driving voltage difference between the driving electrode and the second electrode. Alternatively, a driving electrode may be disposed at a light-emitting side of the anti-blue light device 500 (for example, disposed at the side of the encapsulation layer 700 facing away from the first electrode 100), and the second electrode 200 (for example: a cathode) is reused, so that the anti-blue light device 500 changes its own refractive index under the action of a driving voltage difference between the driving electrode and the second electrode.

In an optical embodiment, the driving signal may be an acoustic signal, and the material of the second film layer is an acousto-optic crystal. Specifically, in the second mode, the acousto-optic crystal in the second film layer receives the acoustic signal and changes its own refractive index under the action of the acoustic signal, so that the refractive index of the second film layer is increased. On the premise of satisfying the Bragg formula, the blue light in the range of 420 nm-460 nm in the blue light spectrum is effectively reflected, so that the proportion of the intensity of the blue light in the range of 420 nm-460 nm in the blue light spectrum of the emitted light incident into the air is reduced. It should be noted that the specific type of the acousto-optic crystal may be determined according to the actual situation, which is not limited by the embodiments of the present disclosure herein.

In an optical embodiment, the driving signal is an optical signal, and the material of the second film layer is a photonic crystal. Specifically, in the second mode, the photonic crystal in the second film layer receives the optical signal and changes its own refractive index under the action of the optical signal, so that the refractive index of the second film layer is increased. On the premise of satisfying the Bragg formula, the blue light in the range of 420 nm-460 nm in the blue light spectrum is effectively reflected, so that the proportion of the intensity of the blue light in the range of 420 nm-460 nm in the blue light spectrum of the emitted light incident into the air is reduced. It should be noted that the specific type of the photonic crystal may be determined according to the actual situation, which is not limited by the embodiments of the present disclosure herein.

In an optical embodiment, when the driving signal is the acoustic signal or the optical signal, the reception and generation of the acoustic signal and the optical signal may be implemented in a manner similar to the method of disposing the driving electrode provided in the embodiment of the present disclosure described above when the driving signal is the electrical signal, which will not be repeated here.

In order to enable a person skilled in the art to understand the present disclosure more clearly, the anti-blue light device of the present disclosure is described in detail through the following embodiments.

In an optical embodiment, the anti-blue light device includes six refractive index adjustment layers arranged in layer configuration. In the first mode, the refractive index of the first film layer of the refractive index adjustment layer is 1.64, and the refractive index of the second film layer is 1.65. In the second mode, the refractive index of the first film layer of the refractive index adjustment layer is 1.64, and the refractive index of the second film layer is 1.74. The incident angle of the incident light in the second mode is 90°. The thickness of each refractive index adjustment layer (equivalent to the distance between the centers of the first film layers in two adjacent refractive index adjustment layers or the distance between the centers of the second film layers in two adjacent refractive index adjustment layers) is calculated to be 134 nm based on the Bragg formula. In the anti-blue light device, the thickness of the first film layer is the same as the thickness of the second film layer, and the thickness of the anti-blue light device is 6×134=804 μm. When the anti-blue light device is converted from the first mode to the second mode under the adjustment of the driving signal, because the second film layer satisfies the Bragg formula, it may reflect the effective blue light with a wavelength in the range of 420 nm-460 nm, and the blue light with a wavelength higher than 460 nm is basically unaffected, thereby the proportion of harmful blue light in the emitted light is reduced and the eye protection effect of the device is improved.

The anti-blue light device provided by the present disclosure includes: at least one refractive index adjustment layer arranged in layer configuration, wherein the refractive index adjustment layer includes the first film layer and the second film layer arranged in layer configuration; the first film layer is disposed adjacent to the light incident surface of the anti-blue light device, and the refractive index of the second film layer is adjustable under the action of driving signal; in the first mode, the absolute value of the difference between the refractive index of the first film layer and the refractive index of the second film layer is less than or equal to the first threshold; and in the second mode, the difference between the refractive index of the second film layer and the refractive index of the first film layer is greater than or equal to the second threshold, the second threshold is greater than the first threshold. In the present application, the second film layer having an adjustable refractive index is provided, and the refractive index of the second film layer is adjusted by the driving signal, so that the second film layer in the second mode reflects the emitted light in the wavelength range of the harmful light, thereby the intensity of the emitted light in the wavelength range of the harmful light is reduced and an effective eye protection effect is achieved.

Based on the same inventive concept, a light-emitting device is provided by an embodiment of the present application. FIG. 5 exemplarily shows a schematic structural diagram of a light-emitting device according to the present disclosure. As shown in FIG. 5, the light-emitting device includes: at least one light-emitting unit 300; and the anti-blue light device 500 as described in the embodiment of the present disclosure. The anti-blue light device 500 is located at a light-emitting side of the at least one light-emitting unit 300.

If optical parameters of the light-emitting unit are not limited, the harmful blue light may not be filtered out when the light passes through the light-emitting device, which may cause the proportion of harmful blue light in the range of 420 nm-460 nm in the light incident into the refractive index adjustment layer to be too high, and even through the refractive index adjustment layer cannot be completely filtered out. Therefore, it is necessary to filter the harmful blue light in the light-emitting device in advance to improve the eye protection effect of the refractive index adjustment layer. Specifically, in an embodiment of the present disclosure, the light-emitting device includes a plurality of light-emitting units 300, and the plurality of light-emitting units 300 are arranged in layer configuration in a light-emitting direction of the light-emitting units 300. A target parameter value of at least one of the plurality of light-emitting units 300 is greater than or equal to a first critical value and less than or equal to a second critical value. A sum of target parameter values of all light-emitting units 300 is greater than or equal to a first total critical value and less than or equal to a second total critical value. The first total critical value is a product of the first critical value and the quantity of the light-emitting units, and the second total critical value is a product of the second critical value and the quantity of the light-emitting units. The target parameter value is at least one of a wavelength corresponding to an intrinsic spectral peak, an intrinsic spectral full width at half maximum, and an intensity of an intrinsic spectral target wavelength.

Exemplarily, the light-emitting device includes a first light-emitting unit, a second light-emitting unit and a third light-emitting unit arranged in layer configuration. The target parameter values of the light-emitting units satisfy that the target parameter values of any one, two or three of the first light-emitting unit, the second light-emitting unit and the third light-emitting unit are greater than or equal to the first critical value and less than or equal to the second critical value, and the sum of the target parameter values of the first light-emitting unit, the second light-emitting unit and the third light-emitting unit is greater than or equal to the first total critical value and less than or equal to the second total critical value.

In an embodiment of the present application, the target parameters of a plurality of light-emitting units arranged in layer configuration in the light-emitting device are limited, so that the target parameter value of the at least one light-emitting unit in the light-emitting device satisfies a range of the critical value, and meanwhile, the target parameter values of all light-emitting units satisfy a range of the total critical value. Under the refraction action of the plurality of light-emitting units satisfying the above-mentioned ranges of the critical value and the total critical value, after light containing a large amount of harmful blue light in the range of 420 nm-460 nm passes through the plurality of light-emitting units of the light-emitting device, the proportion of harmful blue light that is greater than or equal to 40% in the light is reduced to less than 40%, so that the proportion of harmful blue light has been reduced when the light is incident into the anti-blue light device, and the eye protection effect of the anti-blue light device is improved.

In an embodiment of the present disclosure, the target parameter value is at least one parameter value of an intrinsic spectrum of the light-emitting unit and includes at least one of a wavelength corresponding to an intrinsic spectral peak, an intrinsic spectral full width at half maximum and an intensity of an intrinsic spectral target wavelength. For the plurality of light-emitting units in the light-emitting device, at least one target parameter value satisfies that the target parameter value of at least one light-emitting unit in the light-emitting device is greater than or equal to the first critical value and less than or equal to the second critical value, and meanwhile, the sum of the target parameter values of all light-emitting units is greater than or equal to the first total critical value and less than or equal to the second total critical value.

Exemplarily, for the light-emitting device provided with three light-emitting units, when the target parameter value is the wavelength corresponding to the intrinsic spectral peak, the wavelength corresponding to an intrinsic spectral peak of the at least one light-emitting unit (any one, any two, or three light-emitting units) is greater than or equal to the first critical value of the wavelength and less than or equal to the second critical value of the wavelength, and meanwhile, the sum of wavelengths corresponding to the intrinsic spectral peaks of all light-emitting units is greater than or equal to the first total critical value (three times the first critical value of the wavelength) of the wavelength and less than or equal to the second total critical value (three times the second critical value of the wavelength) of the wavelength. For a light-emitting device provided with four light-emitting units, when the target parameter value is the intrinsic spectral full width at half maximum, the intrinsic spectral full width at half maximum of the at least one light-emitting unit (any one, any two, any three or four light-emitting units) is greater than or equal to the first critical value of the full width at half maximum and less than or equal to the second critical value of the full width at half maximum, and meanwhile, the sum of the intrinsic spectral full widths at half maximum of all light-emitting units is greater than or equal to the first total critical value (four times the first critical value of the full width at half maximum) of the full width at half maximum and less than or equal to the second total critical value (four times the second critical value of the full width at half maximum) of the full width at half maximum. It should be noted that the above-mentioned examples are only two optical ways proposed to enable a person skilled in the art to better understand the technical solution of the present disclosure, and the specific type of target parameters and the quantity of the light-emitting units are determined according to the actual situation, which is not limited by the present disclosure herein.

In an optical embodiment, when the target parameter value is the wavelength corresponding to the intrinsic spectral peak, the first critical value is a first wavelength, and the first wavelength is greater than or equal to 455 nm and less than or equal to 465 nm. The second critical value is a second wavelength, and the second wavelength is greater than or equal to 465 nm and less than or equal to 475 nm. Exemplarily, the first wavelength is equal to 460 nm, and the second wavelength is equal to 470 nm. At this moment, the light-emitting unit satisfies the following formula:

$$460 \leq {λ}_{n} \leq 470 ; \\ 460 \times N \leq ( {λ}_{1} + {λ}_{2} + … + {λ}_{N} ) \leq 470 \times N ;$$

wherein λₙ is the wavelength corresponding to the intrinsic spectral peak of at least one light-emitting unit in the light-emitting device, and n is at least one of 1-N. N is the quantity of the light-emitting units in the light-emitting device, λ₁ is a wavelength corresponding to an intrinsic spectral peak of the first light-emitting unit, λ₂ is a wavelength corresponding to an intrinsic spectral peak of the second light-emitting unit, and λ_{N} is a wavelength corresponding to an intrinsic spectral peak of an N-th light-emitting unit.

It should be noted that the above-mentioned example is only a preferred way proposed to enable a person skilled in the art to better understand the technical solution of the present disclosure, and the specific numerical values of the first wavelength and the second wavelength may be determined according to the actual situation, which is not limited by the present disclosure herein.

In an optical embodiment, when the target parameter value is the intrinsic spectral full width at half maximum, the first critical value is a first full width at half maximum, and the first full width at half maximum is greater than or equal to 5 nm and less than or equal to 15 nm. The second critical value is a second full width at half maximum, and the second full width at half maximum is greater than or equal to 25 nm and less than or equal to 35 nm. Exemplarily, the first full width at half maximum is equal to 10 nm, and the second full width at half maximum is equal to 30 nm. At this moment, the light-emitting unit satisfies the following formula:

$$10 \leq {FWHM}_{n} \leq 30 ; \\ 10 \times N \leq ( {FWHM}_{1} + {FWHM}_{2} + … + {FWHM}_{N} ) \leq 30 \times N ,$$

wherein FWHMₙ is the intrinsic spectral full width at half maximum of the at least one light-emitting unit in the light-emitting device, and n is at least one of 1-N. N is the quantity of the light-emitting units in the light-emitting device, FWHM₁ is an intrinsic spectral full width at half maximum of the first light-emitting unit, FWHM₂ is an intrinsic spectral full width at half maximum of the second light-emitting unit, and FWHM_{N} is the intrinsic spectral full width at half maximum of an N-th light-emitting unit.

It should be noted that the above-mentioned example is only a preferred way proposed to enable a person skilled in the art to better understand the technical solution of the present disclosure, and the specific numerical values of the first full width at half maximum and the second full width at half maximum may be determined according to the actual situation, which is not limited by the present disclosure herein.

In an optical embodiment, the target wavelength is 450 nm. When the target parameter value is the intensity of the intrinsic spectral target wavelength, the first critical value is a first intensity, and the first intensity is greater than or equal to 0 and less than or equal to 0.1. The second critical value is a second intensity, and the second intensity is greater than or equal to 0.25 and less than or equal to 0.4. Exemplarily, the target wavelength is 450 nm, the first intensity is 0, and the second intensity is 0.35. At this moment, the light-emitting unit satisfies the following formula:

$$0 \leq {A}_{n} \leq 0.35 ; \\ 0 \leq ( {A}_{1} + {A}_{2} + … + {A}_{N} ) \leq 0.35 \times N ;$$

wherein Aₙ is an intensity of an intrinsic spectral target wavelength of the at least one light-emitting unit in the light-emitting device, and n is at least one of 1-N. N is the quantity of the light-emitting units in the light-emitting device, A₁ is an intensity of an intrinsic spectral target wavelength of the first light-emitting unit, A₂ is an intensity of an intrinsic spectral target wavelength of the second light-emitting unit, and A_{N} is an intensity of an intrinsic spectral target wavelength of an N-th light-emitting unit.

It should be noted that the above-mentioned example is only a preferred way proposed to enable a person skilled in the art to better understand the technical solution of the present disclosure, and the specific numerical values of the first intensity and the second intensity may be determined according to the actual situation, which is not limited by the present disclosure herein.

In an embodiment of the present disclosure, a combination of the at least one light-emitting unit satisfying critical value conditions (including the critical value and the total critical value) is disposed in the light-emitting device, and harmful blue light in the light needed to be incident into the anti-blue light device is filtered in advance to reduce the proportion of harmful blue light in the light needed to be incident into the anti-blue light device, so that the proportion of harmful blue light in the light needed to be reflected by the anti-blue light device is within a range that may be processed by the anti-blue light device, and the eye protection effect of the light-emitting device is improved.

In an embodiment of the present disclosure, as shown in FIG. 5, the light-emitting device further includes a first electrode 100 and a second electrode 200, wherein the at least one light-emitting unit 300 is located between the first electrode 100 and the second electrode 200, and the anti-blue light device 500 is disposed at a side of the second electrode 200 facing away from the first electrode 100. The light-emitting device further includes an optical coupling layer 600 disposed between the second electrode 200 and the anti-blue light device 500. The light-emitting device further includes at least one connection layer 400, wherein each connection layer 400 is disposed between two adjacent light-emitting units 300; the connection layer includes a P-type doped layer and an N-type doped layer arranged in layer configuration. The N-type doped layer is disposed adjacent to a light-emitting surface of the light-emitting unit and the P-type doped layer is disposed adjacent to a light incident surface of the light-emitting unit. The light-emitting device further includes an encapsulation layer 700 disposed at a side of the anti-blue light device 500 facing away from the first electrode 100.

It should also be noted that the intensity of a microcavity formed by the light-emitting device affects the width of the intrinsic spectrum. Specifically, since the microcavity formed by the light-emitting device may narrow the intrinsic spectrum, the smaller the intensity of the microcavity, the narrower the intrinsic spectrum of the emitted light. The narrower the intrinsic spectrum, the greater the proportion of the harmful blue light. Therefore, in order to further reduce the proportion of the harmful blue light in the light emitted from the light-emitting device, it is necessary to increase the intensity of the microcavity by increasing the thickness of the second electrode 200 and/or the thickness of the optical coupling layer 600. In an optical embodiment, the thickness of the second electrode 200 is greater than or equal to 12 nm. A product of the refractive index of the optical coupling layer 600 and the thickness of the optical coupling layer 600 is greater than or equal to 150.

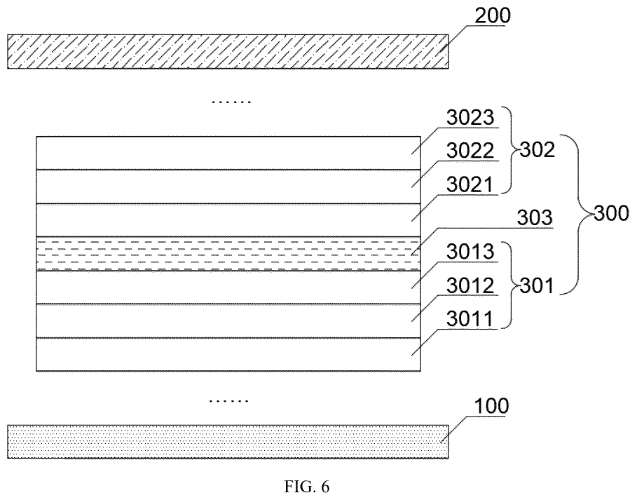

In an optical embodiment, FIG. 6 exemplarily shows a schematic structural diagram of a light-emitting unit according to the present disclosure. As shown in FIG. 6, each light-emitting unit 300 includes: a light-emitting layer 303 disposed between the first electrode 100 and the second electrode 200; a first carrier layer 301 disposed between the first electrode 100 and the light-emitting layer 303; and a second carrier layer 302 disposed between the second electrode 200 and the light-emitting layer 303.

In an optical embodiment, the first carrier layer includes at least one of a hole injection layer (HIL) 3011, a hole transport layer (HTL) 3012 and an electron block layer (EBL) 3013. The hole injection layer 3011, the hole transport layer 3012 and the electron block layer 3013 are sequentially arranged in layer configuration between the first electrode 100 and the light-emitting layer 303 along a first direction, and the first direction is a direction pointing from the first electrode 100 to the second electrode 200. The electron block layer 3013 plays a role in blocking the diffusion of electrons transported by the light-emitting layer 303, electrons and holes are restricted in the light-emitting layer, at the same time, an injection barrier is reduced, the accumulation of interface charges is reduced, the deterioration of the interface is delayed, and thus the service life of the sub-pixels can be extended. It should be noted that the first carrier layer 301 may include only any one of the hole injection layer 3011, the hole transport layer 3012 and the electron block layer 3013, or may include any two of the hole injection layer 3011, the hole transport layer 3012 and the electron block layer 3013, or may include the hole injection layer 3011, the hole transport layer 3012 and the electron block layer 3013. Specifically, the first carrier layer 301 may be disposed according to the actual situation, which is not limited by the present disclosure.

Preferably, as shown in FIG. 6, the first carrier layer 301 includes a hole injection layer 3011 disposed at a side of the first electrode 100 adjacent to the light-emitting layer 303; a hole transport layer 3012 disposed at a side of the hole injection layer 3011 facing away from the first electrode 100; and an electron block layer 3013 disposed at a side of the hole transport layer 3012 facing away from the first electrode 100.

In an optical embodiment, the second carrier layer 302 includes at least one of a hole block layer (HBL) 3021, an electron transport layer (ETL) 3022 and an electron injection layer (EIL) 3023. The hole block layer 3021, the electron transport layer 3022 and the electron injection layer 3023 are sequentially arranged in layer configuration between the light-emitting layer 303 and the second electrode 200 along the first direction. The hole block layer 3021 can play a role in blocking the diffusion of holes transported by the light-emitting layer 303, the holes are restricted in the light-emitting layer, at the same time, an injection barrier is reduced, the accumulation of interface charges is reduced, the deterioration of the interface is delayed, and thus the service life of the pixel may be extended. It should be noted that the second carrier layer 302 may include only any one of the hole block layer 3021, the electron transport layer 3022 and the electron injection layer 3023, or may include any two of the hole block layer 3021, the electron transport layer 3022 and the electron injection layer 3023, or may include the hole block layer 3021, the electron transport layer 3022 and the electron injection layer 3023. Specifically, the second carrier layer 302 may be disposed according to the actual situation, which is not limited by the present disclosure.

Preferably, the second carrier layer 302 includes a hole block layer 3021 disposed at a side of the light-emitting layer 303 facing away from the first electrode 100; an electron transport layer 3022 disposed at a side of the hole block layer 3021 facing away from the first electrode 100; and an electron injection layer 3023 disposed at a side of the electron transport layer 3022 facing away from the first electrode 100.

In order to enable a person skilled in the art to understand the present disclosure more clearly, the light-emitting device of the present disclosure is described in detail through the following embodiments.

In a comparative example for comparison, a light-emitting device including one light-emitting unit is provided. In the light-emitting device of the comparative example, a product of the refractive index of the optical coupling layer and the thickness of the optical coupling layer is less than 150, and the thickness of the second electrode is less than 12 nm. In the light-emitting device of this comparative example, the light-emitting unit has a wavelength corresponding to an intrinsic spectral peak of less than 460 nm, an intrinsic full width at half maximum of greater than 30 nm, and an intensity at the wavelength of 450 nm of the intrinsic spectrum of greater than 0.35 and less than 1. In the light emitted from the light-emitting device of the comparative example, the proportion of the intensity of the blue light with a wavelength in the range of 420 nm-460 nm is greater than 40% and less than 100%.

### Embodiment 1

The light-emitting device provided by the embodiment 1 includes one light-emitting unit. In the light-emitting device provided by the embodiment 1, a product of the refractive index of the optical coupling layer and the thickness of the optical coupling layer is greater than or equal to 150, and the thickness of the second electrode is greater than or equal to 12 nm. In the light-emitting device provided by the embodiment 1, the light-emitting unit has a wavelength corresponding to an intrinsic spectral peak of greater than or equal to 460 nm and less than or equal to 470 nm, an intrinsic full width at half maximum of greater than or equal to 10 nm and less than or equal to 30 nm, and an intensity at the wavelength of 450 nm of the intrinsic spectrum of greater than or equal to 0 and less than or equal to 0.35. In the light emitted from the light-emitting device of the embodiment 1, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 2

The light-emitting device provided by the embodiment 2 includes two light-emitting units. In the light-emitting device provided by the embodiment 2, a product of the refractive index of the optical coupling layer and the thickness of the optical coupling layer is greater than or equal to 150, and the thickness of the second electrode is greater than or equal to 12 nm. In the light-emitting device provided by the embodiment 2, the two light-emitting units have a wavelength corresponding to an intrinsic spectral peak of greater than or equal to 460 nm and less than or equal to 470 nm, an intrinsic full width at half maximum of greater than or equal to 10 nm and less than or equal to 30 nm, and an intensity at the wavelength of 450 nm of the intrinsic spectrum without range limitation. A sum of the wavelengths corresponding to the intrinsic spectral peaks of the two light-emitting units is greater than or equal to 920 nm and less than or equal to 940 nm. A sum of the intrinsic full widths at half maximum of the two light-emitting units is greater than or equal to 20 nm and less than or equal to 60 nm. A sum of the intensities at the wavelength of 450 nm of the intrinsic spectra of the two light-emitting units has no range limitation. In the light emitted from the light-emitting device of the embodiment 2, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 3

The light-emitting device provided by the embodiment 3 includes two light-emitting units (a first light-emitting unit and a second light-emitting unit). In the light-emitting device provided by the embodiment 3, a product of the refractive index of the optical coupling layer and the thickness of the optical coupling layer is greater than or equal to 150, and the thickness of the second electrode is greater than or equal to 12 nm. In the light-emitting device provided by the embodiment 3, a wavelength corresponding to an intrinsic spectral peak of the first light-emitting unit is greater than or equal to 460 nm and less than or equal to 470 nm, and a wavelength corresponding to an intrinsic spectral peak of the second light-emitting unit is different from the wavelength corresponding to an intrinsic spectral peak of the first light-emitting unit. An intrinsic full width at half maximum of the first light-emitting unit is greater than or equal to 10 nm and less than or equal to 30 nm, and an intrinsic full width at half maximum of the second light-emitting unit is different from the intrinsic full width at half maximum of the first light-emitting unit. The intensities at the wavelength of 450 nm of the intrinsic spectra of the first light-emitting unit and the second light-emitting unit have no range limitation. A sum of the wavelengths corresponding to the intrinsic spectral peaks of the two light-emitting units is greater than or equal to 920 nm and less than or equal to 940 nm. A sum of the intrinsic full widths at half maximum of the two light-emitting units is greater than or equal to 20 nm and less than or equal to 60 nm. A sum of the intensities at the wavelength of 450 nm of the intrinsic spectra of the two light-emitting units has no range limitation. In the light emitted from the light-emitting device of the embodiment 3, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 4

The light-emitting device provided by the embodiment 4 includes two light-emitting units (a first light-emitting unit and a second light-emitting unit). In the light-emitting device provided by the embodiment 4, a product of the refractive index of the optical coupling layer and the thickness of the optical coupling layer is greater than or equal to 150, and the thickness of the second electrode is greater than or equal to 12 nm. In the light-emitting device provided by the embodiment 4, a wavelength corresponding to an intrinsic spectral peak of the first light-emitting unit is greater than or equal to 460 nm and less than or equal to 470 nm, and a wavelength corresponding to an intrinsic spectral peak of the second light-emitting unit has no range limitation. An intrinsic full width at half maximum of the first light-emitting unit is greater than or equal to 10 nm and less than or equal to 30 nm, and an intrinsic full width at half maximum of the second light-emitting unit has no range limitation. The intensities at the wavelength of 450 nm of the intrinsic spectra of the first light-emitting unit and the second light-emitting unit are greater than or equal to 0 and less than or equal to 0.35. A sum of the wavelengths corresponding to the intrinsic spectral peaks of the two light-emitting units is greater than or equal to 920 nm and less than or equal to 940 nm. A sum of the intrinsic full widths at half maximum of the two light-emitting units is greater than or equal to 20 nm and less than or equal to 60 nm. A sum of the intensities at the wavelength of 450 nm of the intrinsic spectra of the two light-emitting units is greater than or equal to 0 and less than or equal to 0.7. In the light emitted from the light-emitting device of the embodiment 4, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 5

The light-emitting device provided by the embodiment 5 includes two light-emitting units (a first light-emitting unit and a second light-emitting unit). In the light-emitting device provided by the embodiment 5, a product of the refractive index of the optical coupling layer and the thickness of the optical coupling layer is greater than or equal to 150, and the thickness of the second electrode is greater than or equal to 12 nm. In the light-emitting device provided by the embodiment 5, a wavelength corresponding to an intrinsic spectral peak of the first light-emitting unit is greater than or equal to 460 nm and less than or equal to 470 nm, and a wavelength corresponding to an intrinsic spectral peak of the second light-emitting unit has no range limitation. An intrinsic full width at half maximum of the first light-emitting unit is greater than or equal to 10 nm and less than or equal to 30 nm, and an intrinsic full width at half maximum of the second light-emitting unit has no range limitation. The intensity at the wavelength of 450 nm of the intrinsic spectrum of the first light-emitting unit is greater than or equal to 0 and less than or equal to 0.35, and the intensity at the wavelength of 450 nm of the intrinsic spectrum of the second light-emitting unit is different from the intensity at the wavelength of 450 nm of the intrinsic spectrum of the first light-emitting unit. A sum of the wavelengths corresponding to the intrinsic spectral peaks of the two light-emitting units is greater than or equal to 920 nm and less than or equal to 940 nm. A sum of the intrinsic full widths at half maximum of the two light-emitting units is greater than or equal to 20 nm and less than or equal to 60 nm. A sum of the intensities at the wavelength of 450 nm of the intrinsic spectra of the two light-emitting units is greater than or equal to 0 and less than or equal to 0.7. In the light emitted from the light-emitting device of the embodiment 5, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 6

The light-emitting device provided by the embodiment 6 includes three light-emitting units. In the light-emitting device provided by the embodiment 6, a product of the refractive index of the optical coupling layer and the thickness of the optical coupling layer is greater than or equal to 150, and the thickness of the second electrode is greater than or equal to 12 nm. In the light-emitting device provided by the embodiment 6, a wavelength corresponding to an intrinsic spectral peak of any one of the three light-emitting units is greater than or equal to 460 nm and less than or equal to 470 nm, and wavelengths corresponding to intrinsic spectral peaks of the other two light-emitting units have no range limitation. An intrinsic full width at half maximum of any one of the three light-emitting units is greater than or equal to 10 nm and less than or equal to 30 nm, and intrinsic full widths at half maximum of the other two light-emitting units have no range limitation. The intensity at the wavelength of 450 nm of the intrinsic spectrum of any one of the three light-emitting units is greater than or equal to 0 and less than or equal to 0.35, and the intensities at the wavelength of 450 nm of the intrinsic spectra of the other two light-emitting units have no range limitation. A sum of the wavelengths corresponding to the intrinsic spectral peaks of the three light-emitting units is greater than or equal to 1,380 nm and less than or equal to 1,410 nm. A sum of the intrinsic full widths at half maximum of the three light-emitting units is greater than or equal to 30 nm and less than or equal to 90 nm. A sum of the intensities at the wavelength of 450 nm of the intrinsic spectra of the three light-emitting units is greater than or equal to 0 and less than or equal to 1.05. In the light emitted from the light-emitting device of the embodiment 6, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

### Embodiment 7

The light-emitting device provided by the embodiment 7 includes N light-emitting units. In the light-emitting device provided by the embodiment 7, a product of the refractive index of the optical coupling layer and the thickness of the optical coupling layer is greater than or equal to 150, and the thickness of the second electrode is greater than or equal to 12 nm. In the light-emitting device provided by the embodiment 7, a wavelength corresponding to an intrinsic spectral peak of any one of the N light-emitting units is greater than or equal to 460 nm and less than or equal to 470 nm, and wavelengths corresponding to intrinsic spectral peaks of the other N−1 light-emitting units have no range limitation. An intrinsic full width at half maximum of any one of the N light-emitting units is greater than or equal to 10 nm and less than or equal to 30 nm, and intrinsic full widths at half maximum of the other N−1 light-emitting units have no range limitation. The intensity at the wavelength of 450 nm of the intrinsic spectrum of any one of the N light-emitting units is greater than or equal to 0 and less than or equal to 0.35, and the intensities at the wavelength of 450 nm of the intrinsic spectra of the other N−1 light-emitting units have no range limitation. A sum of the wavelengths corresponding to the intrinsic spectral peaks of the N light-emitting units is greater than or equal to N×460 nm and less than or equal to N×470 nm. A sum of the intrinsic full widths at half maximum of the N light-emitting units is greater than or equal to N×10 nm and less than or equal to N×30 nm. A sum of the intensities at the wavelength of 450 nm of the intrinsic spectra of the N light-emitting units is greater than or equal to 0 and less than or equal to N×0.35. In the light emitted from the light-emitting device of the embodiment 7, in the first mode, the proportion of the intensity of the blue light with a wavelength in the range of 420 nm-460 nm is greater than 30% and less than 40%, and in the second mode, the proportion of the intensity of the blue light with a wavelength in the range of 420 nm-460 nm is greater than 0% and less than or equal to 30%.

From the comparison of the eye protection effects of embodiments 1 to 7 and the comparative example, it can be seen that the light-emitting device provided by the present disclosure satisfies the critical value range and the total critical value range described above and can reduce the proportion of the harmful blue light in the first mode to 30% to 40%. After adjusting to the second mode, the light is further adjusted by the anti-blue light device, and the light-emitting device reduces the proportion of the harmful blue light in the emitted light to 0%-30%, the eye protection effect of the light-emitting device is effectively improved.

Based on the same inventive concept, a display apparatus is provided by an embodiment of the present disclosure, which includes a base substrate and a plurality of light-emitting devices as described in the embodiment of the present disclosure disposed on the base substrate.

In an embodiment of the present disclosure, the display apparatus may be a display or a product including a display. The display may be a flat panel display (FPD), a micro display, or the like. If classified based on whether users can see a scene on the back of the display, the display may be a transparent display or an opaque display. It should be noted that the display apparatus may be specifically determined according to the actual situation, which is not limited by the present disclosure herein.

The above-described device embodiments are merely illustrative, wherein the units that are described as separate components may or may not be physically separate, and the components that are displayed as units may or may not be physical units; in other words, they may be located at the same one location, and may also be distributed to a plurality of network units. Some or all of the modules may be selected according to the actual demands to realize the purposes of the solutions of the embodiments. A person skilled in the art can understand and implement the technical solutions without paying creative work.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “include” does not exclude elements or steps that are not listed in the claims. The word “a” or “one” preceding an element does not exclude the existing of a plurality of such elements. The present disclosure may be implemented by means of hardware including several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. An anti-blue light device, comprising:
at least one refractive index adjustment layer arranged in layer configuration, wherein each of the at least one refractive index adjustment layer comprises a first film layer and a second film layer arranged in layer configuration; the first film layer is disposed adjacent to a light incident surface of the anti-blue light device, and a refractive index of the second film layer is adjustable under an action of a driving signal;
wherein in a first mode, an absolute value of a difference between a refractive index of the first film layer and the refractive index of the second film layer is less than or equal to a first threshold; and in a second mode, the difference between the refractive index of the second film layer and the refractive index of the first film layer is greater than or equal to a second threshold, and the second threshold is greater than the first threshold.

2. The anti-blue light device according to claim 1, wherein the first threshold is greater than or equal to 0 and less than or equal to 0.02; and the second threshold is greater than or equal to 0.04 and less than or equal to 0.06.

3. The anti-blue light device according to claim 1, wherein the refractive index of the first film layer is greater than or equal to a third threshold and less than or equal to a fourth threshold; and
the refractive index of the second film layer is greater than or equal to the third threshold and less than or equal to a fifth threshold.

4. The anti-blue light device according to claim 3, wherein the third threshold is greater than or equal to 1.45 and less than or equal to 1.55; the fourth threshold is greater than or equal to 1.65 and less than or equal to 1.75; and the fifth threshold is greater than or equal to 1.75 and less than or equal to 1.85.

5. The anti-blue light device according to claim 1, wherein a quantity of the at least one refractive index adjustment layer is greater than or equal to 3, and a sum of thicknesses of the at least one refractive index adjustment layer arranged in layer configuration is less than or equal to 20 μm.

6. The anti-blue light device according to claim 1, wherein the driving signal is an electrical signal, and the second film layer comprises a driving electrode and a liquid crystal layer; the driving electrode is configured to form an electric field under an action of the electrical signal to drive deflection of liquid crystal molecules in the liquid crystal layer to adjust the refractive index of the second film layer.

7. The anti-blue light device according to claim 1, wherein the driving signal is an acoustic signal, and the second film layer comprises an acousto-optic crystal; and the acousto-optic crystal is configured to change a refractive index of the acousto-optic crystal under an action of the acoustic signal.

8. The anti-blue light device according to claim 1, wherein the driving signal is an optical signal, and the second film layer comprises a photonic crystal; and the photonic crystal is configured to change a refractive index of the photonic crystal under an action of the optical signal.

9. The anti-blue light device according to claim 1, wherein a material of the first film layer comprises at least one of silicon nitride, silicon oxide and silicon oxynitride.

10. The anti-blue light device according to claim 1, wherein a thickness of the first film layer is the same as a thickness of the second film layer; a quantity of the at least one refractive index adjustment layer is an even number greater than 3, and a thickness of each of the at least one refractive index adjustment layer is greater than or equal to 130 nm and less than or equal to 140 nm.

11. A light-emitting device, comprising:
at least one light-emitting unit; and
the anti-blue light device according to claim 1, wherein the anti-blue light device is located at a light-emitting side of the at least one light-emitting unit.

12. The light-emitting device according to claim 11, wherein the light-emitting device comprises a plurality of light-emitting units, and the plurality of light-emitting units are arranged in layer configuration in a light-emitting direction of the plurality of light-emitting units; and
a target parameter value of at least one of the plurality of the light-emitting units is greater than or equal to a first critical value and less than or equal to a second critical value; a sum of target parameter values of all light-emitting units is greater than or equal to a first total critical value and less than or equal to a second total critical value; the first total critical value is a product of the first critical value and a quantity of the plurality of light-emitting units, and the second total critical value is a product of the second critical value and the quantity of the plurality of light-emitting units; and the target parameter value is at least one of a wavelength corresponding to an intrinsic spectral peak, an intrinsic spectral full width at half maximum and an intensity of an intrinsic spectral target wavelength.

13. The light-emitting device according to claim 12, wherein when the target parameter value is the wavelength corresponding to the intrinsic spectral peak, the first critical value is a first wavelength, and the first wavelength is greater than or equal to 455 nm and less than or equal to 465 nm; and the second critical value is a second wavelength, and the second wavelength is greater than or equal to 465 nm and less than or equal to 475 nm.

14. The light-emitting device according to claim 12, wherein when the target parameter value is the intrinsic spectral full width at half maximum, the first critical value is a first full width at half maximum, and the first full width at half maximum is greater than or equal to 5 nm and less than or equal to 15 nm; and the second critical value is a second full width at half maximum, and the second full width at half maximum is greater than or equal to 25 nm and less than or equal to 35 nm.

15. The light-emitting device according to claim 12, wherein the intrinsic spectral target wavelength is 450 nm; when the target parameter value is an intensity of the intrinsic spectral target wavelength, the first critical value is a first intensity, and the first intensity is greater than or equal to 0 and less than or equal to 0.1; and the second critical value is a second intensity, and the second intensity is greater than or equal to 0.25 and less than or equal to 0.4.

16. The light-emitting device according to claim 11, wherein the light-emitting device further comprises:
a first electrode and a second electrode, wherein the at least one light-emitting unit is located between the first electrode and the second electrode, and the anti-blue light device is disposed at a side of the second electrode facing away from the first electrode.

17. The light-emitting device according to claim 16, wherein a thickness of the second electrode is greater than or equal to 12 nm.

18. The light-emitting device according to claim 16, wherein the light-emitting device further comprises:
an optical coupling layer disposed between the second electrode and the anti-blue light device.

19. The light-emitting device according to claim 18, wherein a product of a refractive index of the optical coupling layer and a thickness of the optical coupling layer is greater than or equal to 150.

20. A display apparatus, comprising a base substrate and the plurality of light-emitting devices according to claim 11 disposed on the base substrate.
